(19) United States
(12) Patent Application Publication
(10) Pub. No.: US 2010/0176363 A1
(43) Pub. Date: Jul. 15, 2010

(54) VARIABLE RESISTANCE ELEMENT AND SEMICONDUCTOR DEVICE PROVIDED WITH THE SAME

(76) Inventors: Kensuke Takahashi, Tokyo (JP); Takashi Nakagawa, Tokyo (JP)

Correspondence Address: Mr. Jackson Chen, 6535 N. STATE HWY 161, IRVING, TX, 75039, US

(21) Appl. No.: 12/602,933

(22) PCT Filed: Apr. 16, 2008
(86) PCT No.: PCT/JP2008/057393

§ 371 Date: Dec. 3, 2009

(30) Foreign Application Priority Data
Jun. 4, 2007 (JP) 2007-147927

(51) Int. Cl. H01L 45/00

(52) U.S. Cl. 257/2; 257/E45.001

(57) ABSTRACT

A variable resistance element includes: a first electrode; a variable resistance material layer formed on the first electrode; and a second electrode formed on this variable resistance material layer. The variable resistance material layer is made of an uncrystallized material including a transition metal oxide, which is an oxide of a transition metal M1, the transition metal oxide containing an oxide of a nontransition metal element M2.

### TECHNICAL FIELD

The present invention relates to a variable resistance element and a semiconductor device provided with the variable resistance element and, more particularly, to a technique for enhancing the performance and reliability of a resistance change type nonvolatile memory element.

### BACKGROUND ART

Nonvolatile memories, which are currently mainstream in the market, use a technique to vary the threshold voltage of a semiconductor transistor by electric charges accumulated within an insulating film located above a channel portion, as typified by a flash memory and a SONOS memory. In order to increase the capacity of the memories, it is essential to miniaturize transistors. However, if an insulating film for retaining charges is thinned down, the charge-retaining capability of the film degrades due to an increase in leakage currents. Accordingly, it has become increasingly difficult to increase the capacity of nonvolatile memories of a charge accumulation transistor type.

Hence, a study is being made in which a transistor is only responsible for a switch function to select a memory cell to be read/written and a memory element is segregated from the transistor as in a DRAM, thereby further miniaturizing the transistor and the memory cell respectively and increasing memory capacity.

As a technology for realizing the miniaturization of a memory element having nonvolatility, active efforts have been made to develop a variable resistance element that uses an electronic element whose electrical resistance value can be varied in two or more ways by some sort of electrical stimulus. In an information storage device of the type, such as a DRAM, in which electrical charges are accumulated in a capacitative element (capacitor), it is unavoidable for a signal voltage to lower along with a decrease in the accumulated amount of charges due to miniaturization. In contrast, electrical resistance generally has a finite value in most cases even if the device is miniaturized. Thus, the information storage device is considered advantageous in the miniaturization of elements as long as principles and materials whereby the resistance value is varied are available.

The operation of such a variable resistance element as described above is exactly that of a switch for selection between an on-state and an off-state. For example, it is in principle also possible to apply the variable resistance element to a wiring configuration changeover switch (selector) within an LSI.

As technologies for varying electrical resistance by means of electrical stimulus, there are some already existing ones. The best-studied of these technologies is a storage device in which a pulse current is flowed through a chalcogenide semiconductor to switch between the states of crystal phases (amorphous state and crystalline state), thereby taking advantage of a difference on the order of two to three digits being present between the electrical resistances of the crystal phases. Such a storage device as described above is generally referred to as a phase-change memory.

On the other hand, it is known that a resistance change is also caused in a metal/metal oxide/metal (hereinafter referred to as an MIM type) structure, in which a metal oxide is sandwiched by electrodes, by applying a large voltage or current. A report of research on phenomena in which a resistance value is caused to change by a voltage or a current has already been made with regard to a variety of materials during a period from the 1950s to the 1960s. For example, a variable resistance element that uses a nickel oxide (NiO) is reported in Non-Patent Document 1 (Solid State Electronics, Vol. 7, p. 785-797, 1964).

FIG. 1 is a schematic cross-sectional view for explaining the fundamental principles of an MIM type variable resistance element. In the figure, reference numeral 1 denotes an upper electrode, reference numeral 2 denotes a variable resistance material layer (NiO layer), and reference numeral 3 denotes a lower electrode. FIG. 2 illustrates the current-voltage characteristics of this MIM type variable resistance element. This variable resistance element can maintain high-resistance off-state characteristics or low-resistance on-state characteristics in a nonvolatile manner even if power is turned off. In addition, the resistive state of the variable resistance element can be switched by applying predetermined voltage/current stimulus as necessary. FIG. 2 illustrates one example of on-state and off-state current-voltage characteristics. If a voltage of Vₜ₂ or higher is applied to an element in a high-resistance off-state (dotted line in FIG. 2), the element changes to a low-resistance on-state and has the electrical characteristics shown by a solid line in FIG. 2. Next, if a voltage of Vₜ₁ or higher is applied to the element in an on-state (solid line in FIG. 2), the element changes to a high-resistance off-state and reverts to the electrical characteristics shown by a dotted line in FIG. 2. The variable resistance element is capable of such operation to repetitively switch between a high-resistance off-state and a low-resistance on-state as described above. Accordingly, this characteristic can be utilized as a circuit-switching nonvolatile memory cell or nonvolatile switch.

In a phase-change memory, a volume change due to a change in crystal phase is generally large. In addition, the phase-change memory requires heating locally to several hundred degrees C., though for a duration as short as several tens of nanoseconds, in order to cause a crystal phase change. Accordingly, the phase-change memory, when used as a memory element or a switch element, has the problem that it is difficult to perform temperature control on a phase-change material. On the other hand, the above-described MIM type variable resistance element does not require heating to such a high temperature as several hundred degrees C. Thus, the MIM type variable resistance element has once again started to draw attention in recent years.

For example, Patent Document 1 (Japanese Patent Laid-Open No. 2006-2108882) and Non-Patent Document 2 (Applied physics letters, Vol. 88, p. 202102, 2006) propose a resistance change type storage device which uses a nickel oxide as a metal oxide layer. In particular, Non-Patent Document 2 describes that a current path (responsible for an on-state) 4 known as a filament is formed in a variable resistance material layer 2 made of a nickel oxide, as illustrated in FIG. 3, and the resistance of an element changes according to the current path's states of junction to an upper electrode 1 and to a lower electrode 3.

In addition, Non-Patent Document 3 (Applied physics letters, Vol. 88, p. 232106, 2006) proposes that, in a resistance switch memory which uses a crystallized nickel oxide as a metal oxide layer, a crystallized conductive oxide made of IrO₂ be located in the boundary faces of this nickel oxide with an upper electrode and with a lower electrode. According to this document, a description is made that the crystallinity of the nickel oxide is improved by locating IrO₂ and the variation of switching characteristics can be suppressed.

### DISCLOSURE OF THE INVENTION

However, the above-described technologies have such problems as described below.

First, since the storage devices described in Patent Document 1 and Non-Patent Document 2 use a crystal of the nickel oxide as the variable resistance material layer, there arises a film thickness distribution of an NiO film attributable to a crystal grain size or a leakage current attributable to a crystal grain boundary, as illustrated in FIG. 4(a). Consequently, the rate of resistance change degrades. In addition, if there is the film thickness distribution in the variable resistance material layer, as illustrated in FIG. 4(b), a distribution also arises in electric field strength applied to the variable resistance material layer. Consequently, the filament to serve as the current path is formed nonuniformly. As a result, there arises a mixture of regions which go to an on-state as the filament serving as the current path interconnects the upper and lower electrodes and regions which remain in an off-state as the filament, even if formed, fails to interconnect the upper and lower electrodes. Consequently, a variation is caused in the switching probability of elements. In FIG. 4, reference numeral 1 denotes the upper electrode, reference numeral 2 denotes the variable resistance material layer, reference numeral 3 denotes the lower electrode, reference numeral 6 denotes the leakage current flowing through the crystal grain boundary, reference numerals 7 and 8 denote leakage currents, reference numeral 9 denotes a filament forming a current path for an on-state, and reference numeral 10 denotes a filament failing to form a current path for an on-state.

In addition, since the nickel oxide is a transition metal oxide, an oxygen defect is in general liable to occur within a film and this defect can be a cause for an increase in leakage currents. For this reason, if an element is put into repetitive operation, a new defect is generated within an NiO film due to a leakage current, thus causing the leakage current to increase and resistance reduction to progress. As a result, there arises a decrease in the on-off ratio of the element or a variation in the characteristics thereof, thus degrading the reliability of the element.

Second, Non-Patent Document 3 describes that, in the storage device described discussed therein, the crystallinity of the nickel oxide is improved by locating the conductive oxide made of crystallized IrO₂, whereas a leakage current in an off-state increases and a switching ratio decreases, compared with a case where IrO₂ is not located. This is considered to be due to the reason that the crystallized conductive metal oxide (IrO₂) is located in the boundary face between the electrode and the nickel oxide.

Such problems as described above become intrinsic, if a transition metal oxide having a crystal phase, let alone a nickel oxide, is used for a variable resistance material.

An object of the present invention is to provide a variable resistance element having improved element characteristics and reliability, and a semiconductor device provided with the variable resistance element.

According to one aspect of the present invention, there is provided a variable resistance element including:

a first electrode;

a variable resistance material layer formed on the first electrode; and

a second electrode formed on this variable resistance material layer,

wherein the variable resistance material layer is made of an uncrystallized material including a transition metal oxide, which is an oxide of a transition metal M1, the transition metal oxide containing an oxide of a nontransition metal element M2.

According to another aspect of the present invention, there is provided a semiconductor device including:

a semiconductor substrate;

a transistor formed on this semiconductor substrate; and

the aforementioned variable resistance element electrically connected to this transistor.

According to yet another aspect of the present invention, there is provided a semiconductor device including:

a lower-layer interconnect;

an interlayer insulating film provided on this lower-layer interconnect; and

an upper-layer interconnect provided on this interlayer insulating film,

wherein the semiconductor device further including:

the aforementioned variable resistance element;

a via hole provided in the interlayer insulating film such that the lower-layer interconnect is exposed;

a variable resistance material layer provided within this via hole; and

a conductive portion connecting to the upper-layer interconnect, the conductive portion being provided on the variable resistance material layer such that this via hole is filled with the conductive portion; and

wherein the variable resistance element includes the lower-layer interconnect, the variable resistance material layer, and the conductive portion.

According to the present invention, it is possible to provide a variable resistance element having improved element characteristics and reliability, and a semiconductor device provided with the variable resistance element.

### BRIEF DESCRIPTION OF THE DRAWINGS

FIG. 1 is a schematic cross-sectional view for explaining the fundamental principles of an MIM type variable resistance element;

FIG. 2 is a drawing illustrating the basic resistance change characteristics (current-voltage characteristics) of an MIM type variable resistance element (an element in which a nickel oxide is used for a variable resistance material);

FIG. 3 is a schematic drawing (overhead perspective view) illustrating a local current path responsible for an on-state in an MIM type variable resistance element;

FIG. 4 is a schematic cross-sectional view for explaining the deterioration mechanism of the switching characteristics of an MIM type variable resistance element;

FIG. 5 is a schematic cross-sectional view illustrating the fundamental structure of an MIM type variable resistance element in accordance with one exemplary embodiment of the present invention;

FIG. 6 is a schematic drawing illustrating a state of chemical bonding in a phosphorized nickel oxide;

FIG. 7 is a drawing illustrating a relationship between a phosphorus concentration and an oxygen concentration in a phosphorized nickel oxide;

FIG. 8 is a schematic cross-sectional view illustrating a local current path in the on-state of an MIM type variable resistance element in accordance with one exemplary embodiment of the present invention;

FIG. 9(a) is a cross-sectional view for explaining a manufacturing process of an MIM type variable resistance element in accordance with one exemplary embodiment of the present invention;

FIG. 9(b) is another cross-sectional view for explaining the manufacturing process of the MIM type variable resistance element in accordance with one exemplary embodiment of the present invention;

FIG. 9(c) is yet another cross-sectional view for explaining the manufacturing process of the MIM type variable resistance element in accordance with one exemplary embodiment of the present invention;

FIG. 9(d) is still another cross-sectional view for explaining the manufacturing process of the MIM type variable resistance element in accordance with one exemplary embodiment of the present invention;

FIG. 9(e) is still another cross-sectional view for explaining the manufacturing process of the MIM type variable resistance element in accordance with one exemplary embodiment of the present invention;

FIG. 9(f) is still another cross-sectional view for explaining the manufacturing process of the MIM type variable resistance element in accordance with one exemplary embodiment of the present invention;

FIG. 10 is a drawing illustrating the results of the XPS-based depth-direction composition analysis of a nickel oxide (FIG. 10(a) illustrates results for a non-phosphorized nickel oxide and FIG. 10(b) illustrates results for a phosphorized nickel oxide);

FIG. 11 is a drawing illustrating cross-sectional SEM images of a nickel oxide film (FIG. 11(a) illustrates an SEM image for a non-phosphorized nickel oxide film and FIG. 11(b) illustrates an SEM image for a phosphorized nickel oxide film);

FIG. 12 is a drawing illustrating the results of the XRD measurement of a non-phosphorized nickel oxide film and a phosphorized nickel oxide film;

FIG. 13 is a drawing illustrating the P2p photoelectron spectrum of a phosphorized nickel oxide film;

FIG. 14 is a drawing illustrating the O1s photoelectron spectrums of a non-phosphorized nickel oxide film and a phosphorized nickel oxide film;

FIG. 15 is a drawing illustrating the Ni2p photoelectron spectrums of a non-phosphorized nickel oxide film and a phosphorized nickel oxide film;

FIG. 16 is a drawing illustrating the current-voltage characteristics of an MIM type variable resistance element (FIG. 16(a) illustrates a case where a non-phosphorized nickel oxide film is used, and FIG. 6(b) illustrates a case where a phosphorized nickel oxide film is used);

FIG. 17(a) is a cross-sectional view for explaining a manufacturing process of an MIM type variable resistance element in accordance with another exemplary embodiment of the present invention;

FIG. 17(b) is another cross-sectional view for explaining the manufacturing process of the MIM type variable resistance element in accordance with another exemplary embodiment of the present invention;

FIG. 17(c) is yet another cross-sectional view for explaining the manufacturing process of the MIM type variable resistance element in accordance with another exemplary embodiment of the present invention;

FIG. 17(d) is still another cross-sectional view for explaining the manufacturing process of the MIM type variable resistance element in accordance with another exemplary embodiment of the present invention;

FIG. 17(e) is still another cross-sectional view for explaining the manufacturing process of the MIM type variable resistance element in accordance with another exemplary embodiment of the present invention;

FIG. 17(f) is still another cross-sectional view for explaining the manufacturing process of the MIM type variable resistance element in accordance with another exemplary embodiment of the present invention;

FIG. 17(g) is still another cross-sectional view for explaining the manufacturing process of the MIM type variable resistance element in accordance with another exemplary embodiment of the present invention;

FIG. 17(h) is still another cross-sectional view for explaining the manufacturing process of the MIM type variable resistance element in accordance with another exemplary embodiment of the present invention;

FIG. 17(i) is still another cross-sectional view for explaining the manufacturing process of the MIM type variable resistance element in accordance with another exemplary embodiment of the present invention;

FIG. 18 is a drawing illustrating cross-sectional SEM images of a nickel oxide film (FIGS. 18(a) and 18(b) illustrate SEM images of a non-phosphorized nickel oxide film and FIGS. 18(c) and 18(d) illustrates SEM images of a phosphorized nickel oxide film);

FIG. 19(a) is a cross-sectional view for explaining a manufacturing process of an MIM type variable resistance element in accordance with yet another exemplary embodiment of the present invention;

FIG. 19(b) is another cross-sectional view for explaining the manufacturing process of the MIM type variable resistance element in accordance with yet another exemplary embodiment of the present invention;

FIG. 19(c) is yet another cross-sectional view for explaining the manufacturing process of the MIM type variable resistance element in accordance with yet another exemplary embodiment of the present invention;

FIG. 19(d) is still another cross-sectional view for explaining the manufacturing process of the MIM type variable resistance element in accordance with yet another exemplary embodiment of the present invention;

FIG. 19(e) is still another cross-sectional view for explaining the manufacturing process of the MIM type variable resistance element in accordance with yet another exemplary embodiment of the present invention;

FIG. 19(f) is still another cross-sectional view for explaining the manufacturing process of the MIM type variable resistance element in accordance with yet another exemplary embodiment of the present invention;

FIG. 19(g) is still another cross-sectional view for explaining the manufacturing process of the MIM type variable resistance element in accordance with yet another exemplary embodiment of the present invention;

FIG. 19(h) is still another cross-sectional view for explaining the manufacturing process of the MIM type variable resistance element in accordance with yet another exemplary embodiment of the present invention;

FIG. 19(i) is still another cross-sectional view for explaining the manufacturing process of the MIM type variable resistance element in accordance with yet another exemplary embodiment of the present invention; and

FIG. 20 is a cross-sectional view illustrating a semiconductor device in accordance with one exemplary embodiment of the present invention.

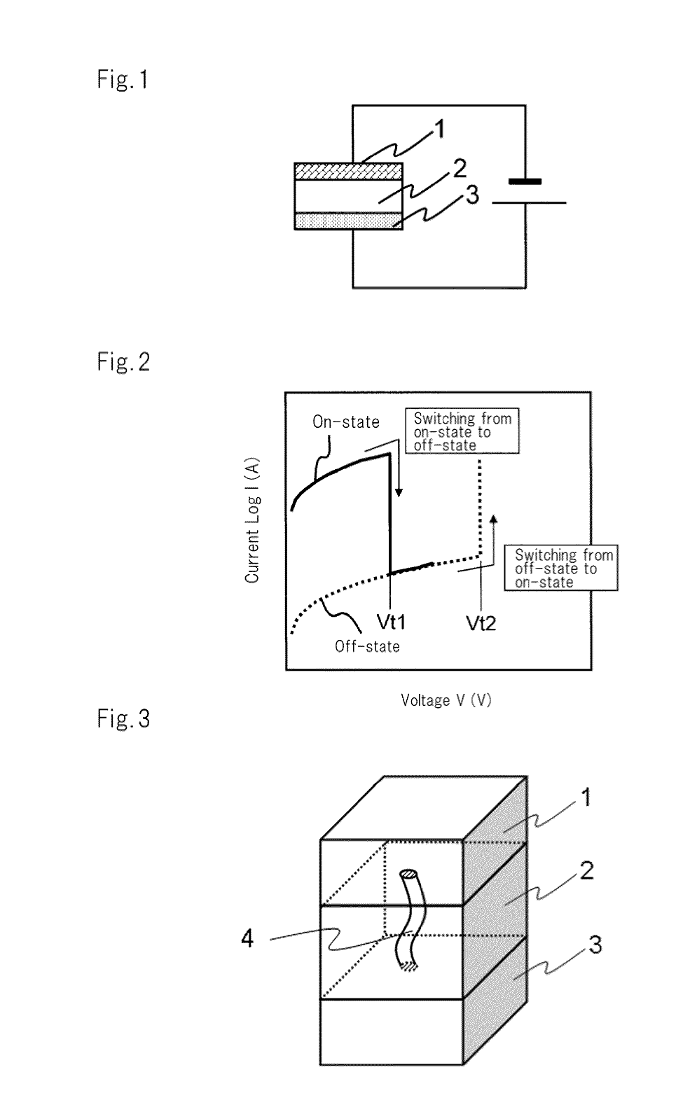

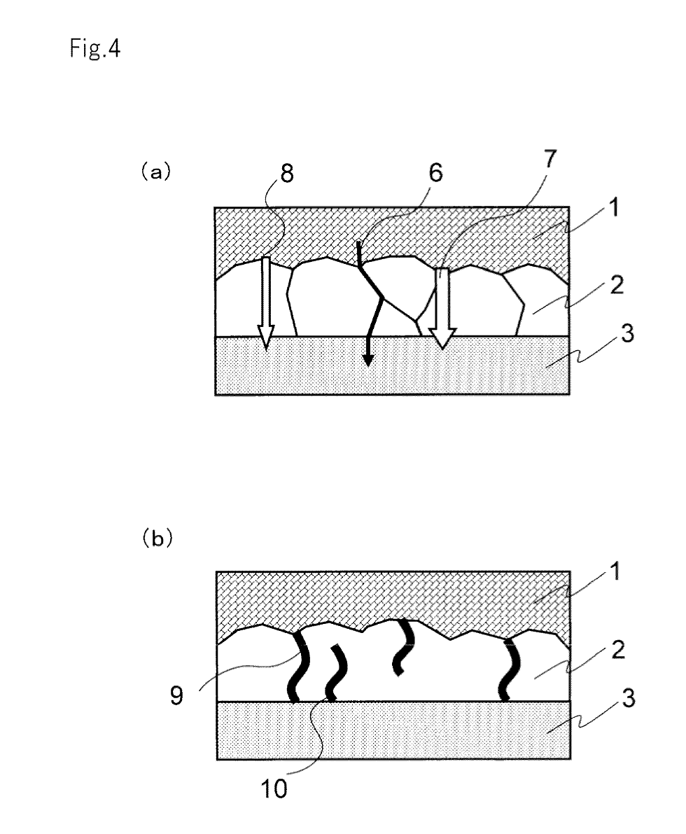

### BEST MODE FOR CARRYING OUT THE INVENTION

According to one exemplary embodiment of the present invention, in a variable resistance element having a conductive layer/variable resistance material layer/conductive layer laminated structure, in which a metal oxide is sandwiched by electrodes, a material for the variable resistance material layer is a transition metal oxide, which is an oxide of a transition metal M1, doped with the oxide component of an element (nontransition metal element) M2 which is other than the transition metal M1 and not a transition metal, preferably a material higher in valence than the transition metal M1 and doped with the oxide component of the nontransition metal element M2, and more preferably a material higher in valence than the transition metal M1, high in electronegativity, and doped with the oxide component of the nontransition metal element M2. In such an element, the variable resistance material is uncrystallized and the oxidized state of the transition metal is further stabilized. By making the variable resistance material uncrystallized, it is possible to reduce a leakage current or a variation in element characteristics resulting from a film thickness distribution (arising due to a crystal grain size) or a crystal grain boundary. In addition, as the result of the transition metal M1 being in a more stable oxidized state, it is possible to suppress degradation in the film quality of the variable resistance material due to defect formation in the transition metal oxide. As a result, it is possible to simultaneously realize improvements in both the switching characteristics and the reliability of the variable resistance element.

The amount of element M2 to be doped into the transition metal oxide, which is an oxide of the transition metal M1, is preferably set within the range of 0.03<R₂<0.5 when the composition ratio of M2 is represented as R₂=M2/(M1+M2). If the composition ratio R₂ of M2 is too low, the transition metal oxide is made insufficiently uncrystallized. Conversely, if R, is too high, the transition metal oxide no longer functions as the variable resistance material. This composition ratio R₂ of M2 is preferably set within the range of 0.05<R₂<0.3 and, more preferably, within the range of 0.05<R₂<0.1. By setting the composition ratio of M2 within such a range as described above, it is possible to make the transition metal oxide uncrystallized while maintaining the resistance change characteristics thereof.

The oxygen (O) composition ratio R_{O} of the transition metal oxide doped with the element M2, when the composition ratio of O is represented as R_{O}=O/(M1+M2), is preferably set within the range of 1.04<R_{O}<1.75 under the condition 0.03<R₂<0.5, more preferably, within the range of 1.07<R_{O}<1.45 under the condition 0.05<R₂<0.3 and, even more preferably, within the range of 1.07<R_{O}<1.15 under the condition 0.05<R₂<0.1. With R_{O} being within such a range of composition ratios as described above, it is possible to obtain a high-quality variable resistance material having less oxygen defects.

Hereinafter, one exemplary embodiment of the present invention will be described according to drawings.

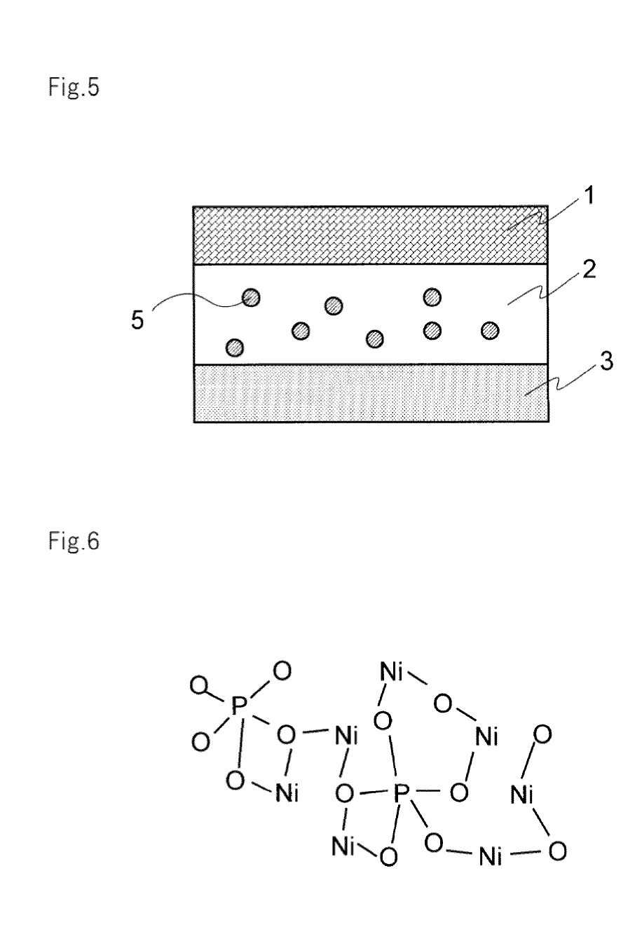

FIG. 5 is a schematic cross-sectional view illustrating the fundamental structure of a variable resistance element in accordance with the present exemplary embodiment. In the figure, reference numeral 1 denotes an upper electrode, reference numeral 2 denotes a variable resistance material layer, reference numeral 3 denotes a lower electrode, and reference numeral 5 denotes an oxide doped into a variable resistance material. The variable resistance element in accordance with the present exemplary embodiment has a metal/variable resistance material/metal MIM type structure in which a metal oxide is sandwiched by electrodes, thereby being a component of a nonvolatile semiconductor memory device. This MIM type laminated structure is constructed of the lower electrode 3 formed on a semiconductor or insulator substrate or on an interlayer insulating film of LSI interconnects, the variable resistance material layer 2 formed on the lower electrode 3 and composed primarily of a transition metal oxide, and the upper electrode 1 formed on the variable resistance material layer 2.

The variable resistance material layer is composed primarily of the transition metal oxide which is an oxide of the transition metal M1, and is made of an uncrystallized material containing at least one type of this oxide 5 of nontransition metal element M2. The oxide of the element M2 is preferably an oxide of an element higher in valence than the transition metal M1 and, more preferably, an oxide of an element higher in valence than the transition metal M1 and high in electronegativity. Even more preferably, the oxide of the element M2 is an oxide of at least one type of metal selected from the group consisting of P, As, Sb, Bi, Se, Te, Po, I, At, B, Al and Si and, particularly preferably, an oxide of P. Two or more types of this oxide may be used in combination.

The above-described transition metal oxide is preferably an oxide of at least one type of metal selected from the group consisting of Ni, Ti, Zr, Fe, V, Mn and Co and, more preferably, an oxide of Ni.

The thickness of the variable resistance material layer can be set within the range of 5 nm to 200 nm. From the viewpoint of element shaping, the thickness is preferably set to 200 nm or less and, more preferably, 100 nm or less. From the viewpoint of film uniformity, the thickness is preferably set to 5 nm or greater. In addition, from the viewpoint of switching voltage reduction, this thickness is more preferably set to 60 nm or less. From the viewpoint of reliability, the thickness is more preferably set to 20 nm or greater.

If the transition metal M1 of the above-described transition metal oxide is Ni and if the element M2 of the above-described doped oxide is P, then the amount of phosphorus (P) doped into the nickel oxide, when the composition ratio of P is represented as R_{P}=P/(P+Ni), is preferably set within the range of 0.03<R_{P}<0.5. If the phosphorus concentration (composition ratio of phosphorus) R_{P} is too low, the nickel oxide is made insufficiently uncrystallized. Conversely, if R_{P} is too high, the nickel oxide no longer functions as a variable resistance material. This phosphorus concentration R_{P} is preferably set within the range of 0.05<R_{P}<0.3 and, more preferably, within the range of 0.1<R_{P}<0.2. By setting the composition ratios of Ni and P within such ranges as described above, it is possible to make the nickel oxide uncrystallized, while maintaining the resistance change characteristics thereof.

The oxygen concentration (composition ratio of oxygen) R_{O} of the P-doped nickel oxide, when the composition ratio of O is represented as R_{O}=O/(P+Ni), is preferably set within the range of 1.04<R_{O}<1.75 under the condition 0.03<R_{P}<0.5, more preferably within the 1.07<R_{O}<1.45 under the condition 0.05<R_{P}<0.3 and, even ore preferably, within the range of 1.07<R_{O}<1.15 under the condition 0.05<R_{P}<0.1. With R_{O} being within such a range of composition ratios as described above, it is possible to obtain a high-quality variable resistance material having less oxygen defects.

FIG. 6 is a schematic drawing illustrating a state of chemical bonding in a nickel oxide containing an oxide component of P. As illustrated in FIG. 6, doping pentavalent P into divalent Ni causes the period of bonding of Ni with oxygen atoms to become irregular. Thus, it is possible to make the nickel oxide uncrystallized.

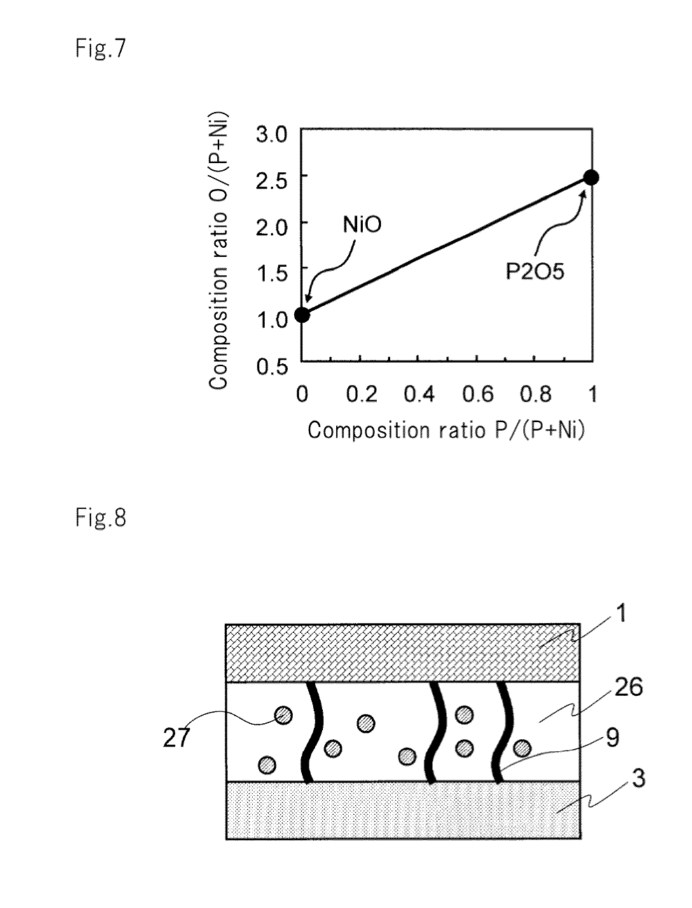

An oxide of divalent Ni forms NiO whose composition ratio of Ni to oxygen (O) is 1:1. On the other hand, an oxide of Ni doped with pentavalent P has a higher composition ratio of oxygen to Ni, compared with NiO. FIG. 7 is a drawing illustrating a relationship between a phosphorus concentration and an oxygen concentration in a nickel oxide in a case where P is doped into the nickel oxide. As illustrated in FIG. 7, the oxygen concentration (composition ratio of O) in the nickel oxide becomes higher as the phosphorus concentration (composition ratio of P) in the nickel oxide becomes higher.

In the nickel oxide containing an oxide component of P, since P is higher in electronegativity than Ni, the amount of charges transferred from Ni to oxygen becomes larger, compared with the amount in NiO. Thus, the state of bonding between Ni and O becomes more stable. Since an oxide of P is an insulator, the oxide does not exhibit any resistance change characteristics. In an on-state, however, a current path known as a filament is formed in an extremely narrow region within the nickel oxide, as illustrated in FIG. 8. Accordingly, the presence of the oxide of P, which is an insulator, within the nickel oxide does not degrade the on-state characteristics of the nickel oxide, as long as the amount of the oxide of P within the nickel oxide is not too large.

Furthermore, as the result that the nickel oxide contains the oxide component of P, excess filaments are prevented from being formed within the nickel oxide. Thus, leakage currents in an off-state are suppressed.

As described above, by making the nickel oxide contain an oxide component of P so as to be uncrystallized, it is possible to reduce a leakage current or a variation in element characteristics resulting from a film thickness distribution (arising due to a crystal grain size) or a crystal grain boundary. In addition, as the result of Ni being in a more stable oxidized state, it is possible to suppress degradation in the film quality of the variable resistance material due to defect formation in the transition metal oxide. As a result, it is possible to simultaneously realize improvements in both the switching characteristics and the reliability of the variable resistance element.

The pair of electrodes that sandwich the variable resistance material layer can be formed of the same material. Alternatively, the electrodes may be formed of electrode materials different from each other. As the electrode material, it is possible to use a metal selected from the group consisting of Pt, Ir, Ru, Ti, Ta, W and Cu, an oxide thereof, or a nitride thereof. Preferably, the electrode material is a metal, a metal oxide or a metal nitride selected from the group consisting of Ru, RuO₂, Ti, TiN, Ta, TaN, W, WN and Cu. These electrode materials are easy to process using a dry etching or CMP (Chemical Mechanical Polishing) technique, and are highly consistent with conventional LSI manufacturing processes. An even more preferable electrode material is a material selected from the group consisting of Ta, TaN and Cu. These materials are used in an interconnection step in an LSI manufacturing process. By applying these materials, it is possible to greatly reduce manufacturing costs for adding a variable resistance element in accordance with the present invention to an LSI. The most preferred electrode material is Cu. By using Cu, it is possible to make an interconnect of an LSI function as an electrode of an MIM type variable resistance element. Thus, it is possible to simultaneously realize both improvements in the performance of the MIM type variable resistance element by the reduction of electrode resistivity and reductions in manufacturing costs.

Hereinafter, exemplary embodiments of the present invention will be described with reference to the accompanying drawings.

### Exemplary Embodiment 1

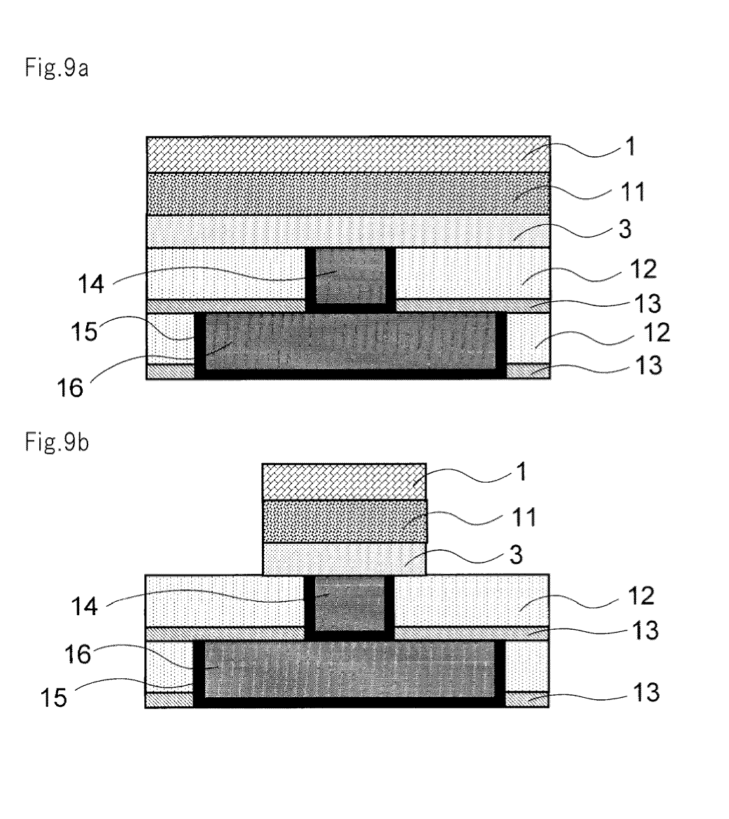

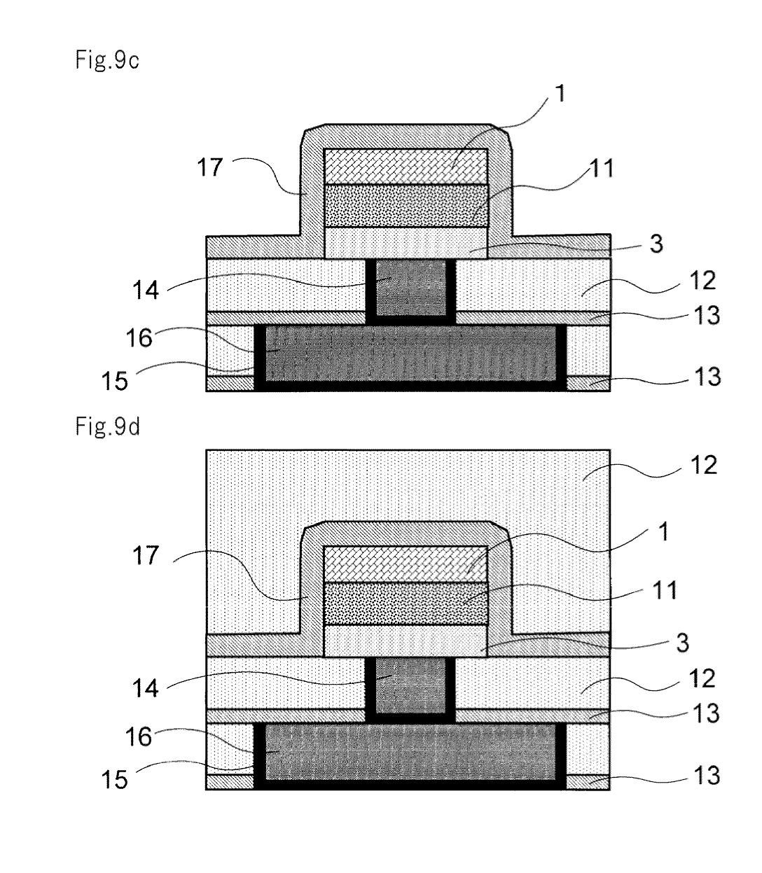

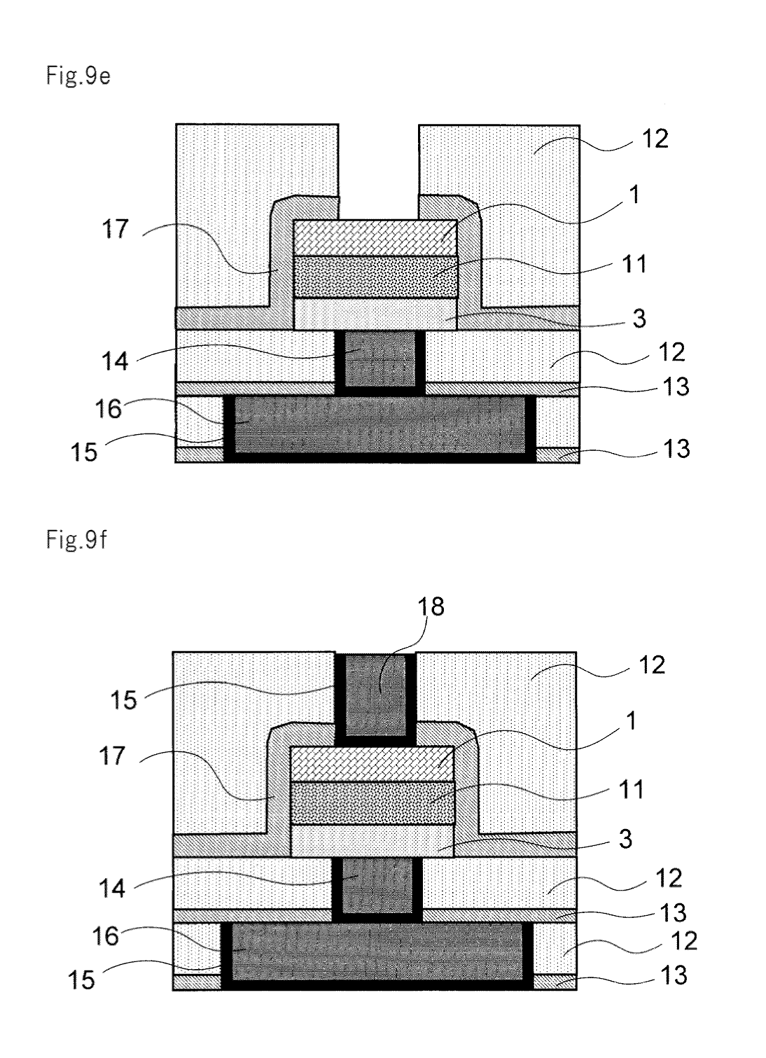

As a first exemplary embodiment of the present invention, FIG. 9(f) illustrates a structural example of an MIM type variable resistance element. The manufacturing process of the MIM type variable resistance element of the present exemplary embodiment will be described using FIGS. 9(a) to (f). This manufacturing process is an example of forming an MIM type variable resistance element to be connected to an interconnect layer of an LSI containing CMOS transistors.

First, as illustrated in FIG. 9(a), a lower interconnect 16 and a lower via interconnect 14 to be connected thereto are formed using a CMP (Chemical Mechanical Polishing) technique and an electrolytic plating technique. The lower interconnect 16 and the lower via interconnect 14 are made of Cu. An interlayer insulating film 12 is a silicon dioxide film formed using a CVD technique. In order to prevent the lower interconnect 16 and the lower via interconnect 14 from reacting with and separating off the interlayer insulating film 12, an interconnect protection film 13 and a barrier film 15 are formed in boundary faces among these components. A silicon carbon nitride (SiCN) is used for the interconnect protection film 13 and a laminated film of tantalum (Ta) and tantalum nitride (TaN) is used for the barrier film 15. After the formation of the lower via interconnect 14, planarization is performed concurrently with exposing a surface of the lower via interconnect by means of CMP.

After that, there are formed a lower electrode layer 3, a variable resistance material layer (phosphorus-doped nickel oxide layer) 11, and an upper electrode layer 1 for an MIM type memory element. In the present exemplary embodiment, both the upper electrode 1 and the lower electrode 3 are made of Ru for ease of processing. Ru for the upper electrode 1 and the lower electrode 3 can be film-formed by means of sputtering.

A phosphorus (P)-doped nickel oxide film is used for the variable resistance material layer 11. The film thickness of this variable resistance material layer 11 can be set within the range of 5 nm to 200 nm. From the viewpoint of element shaping, the thickness is preferably set to 100 nm or less. From the viewpoint of film uniformity, the thickness is preferably set to 5 nm or greater. More preferably, the film thickness is set to 60 nm or less from the viewpoint of switching voltage reduction, and is set to 20 nm or greater from the viewpoint of reliability.

As a method for forming a phosphorus-doped nickel oxide film for constituting the variable resistance material layer 11, sputtering can be used. From the viewpoint of improving film denseness, however, it is preferable to form the phosphorus-doped nickel oxide film using a CVD (Chemical Vapor Deposition) method. By adjusting the flow rate of a raw material gas containing an Ni metal using a mass flow controller and supplying the gas, along with an oxidizing gas, through a showerhead onto a silicon substrate heated to a predetermined temperature, it is possible to form the nickel oxide film.

As the raw material gas containing the Ni metal, it is preferable to use Ni(PF₃)₄. By using an Ni(PF₃)₄ gas, it is possible to dope phosphorus into the nickel oxide film with one gas line alone. In addition, since the Ni(PF₃)₄ gas does not contain carbon, unlike an organic metal (Metal-Organic: MO) raw material gas, it is possible to avoid carbon from being left over in the nickel oxide film. Carbon is a contaminant for an insulating film. Accordingly, if carbon mixes into the insulating film, the insulation characteristics thereof degrade remarkably. In the case of a variable resistance material, the off-state characteristics thereof degrade remarkably.

As a carrier gas, N₂ is used and, as an oxidizing gas, O₂ is used.

The silicon substrate is heated using, a heater operated through a susceptor. The temperature of the substrate can be set within the range of 100° C. to 400° C. Preferably, the temperature is set within the range of 150° C. to 300° C. and, more preferably, within the range of 200° C. to 250° C. If the substrate temperature is too low, the raw material gas has difficulty in making progress in decomposition, the rate of film formation slows down, and the uniformity of the nickel oxide film within a surface of a wafer degrades. Consequently, there arises a problem in a manufacturing process from the viewpoint of throughputs and yields. On the other hand, from the viewpoint of the heat resistance of an interconnect layer, the substrate temperature at the time of film formation is preferably set to 400° C. or lower.

Since the Ni(PF₃)₄ gas contains F in addition to P, F mixes into the nickel oxide film immediately after film formation. This F can, however, be removed by annealing treatment performed after film formation. Annealing is preferably performed in an oxygen atmosphere.

The amount of P to be doped into the nickel oxide film can be controlled by varying film-forming pressure. The film-forming pressure can be set to within the range of 0.001 Torr (1.33×10⁻¹ Pa) to 100 Torr (1.33×10⁴ Pa). In order to obtain a preferred P concentration, however, it is preferable to set the film-forming pressure to within the range of 0.1 Torr (1.33×10 Pa) to 2.5 Torr (3.33×10² Pa).

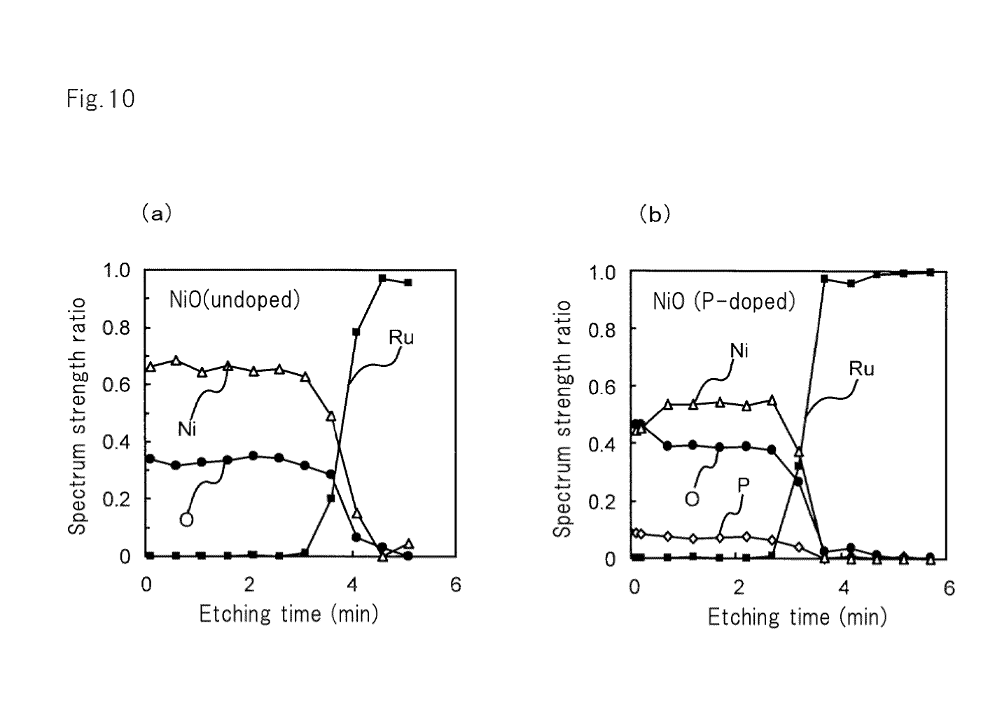

FIG. 10 is a drawing illustrating the results of the XPS-based depth-direction composition analysis of a nickel oxide film formed on Ru. FIGS. 10(a) and 10(b) illustrate the dependence of the strength of a photoelectron spectrum from the nickel oxide film upon an argon sputtering time for a nickel oxide not doped with P and for a nickel oxide doped with P, respectively. As illustrated in FIG. 10(a), it is possible to uniformly dope P into the nickel oxide film by performing film formation under predetermined conditions using an Ni(PF₃)₄ gas. In addition, doping P into the nickel oxide film increases an oxygen concentration in the nickel oxide film. An explanation will be made later with regard to the advantage of an increase in the oxygen concentration.

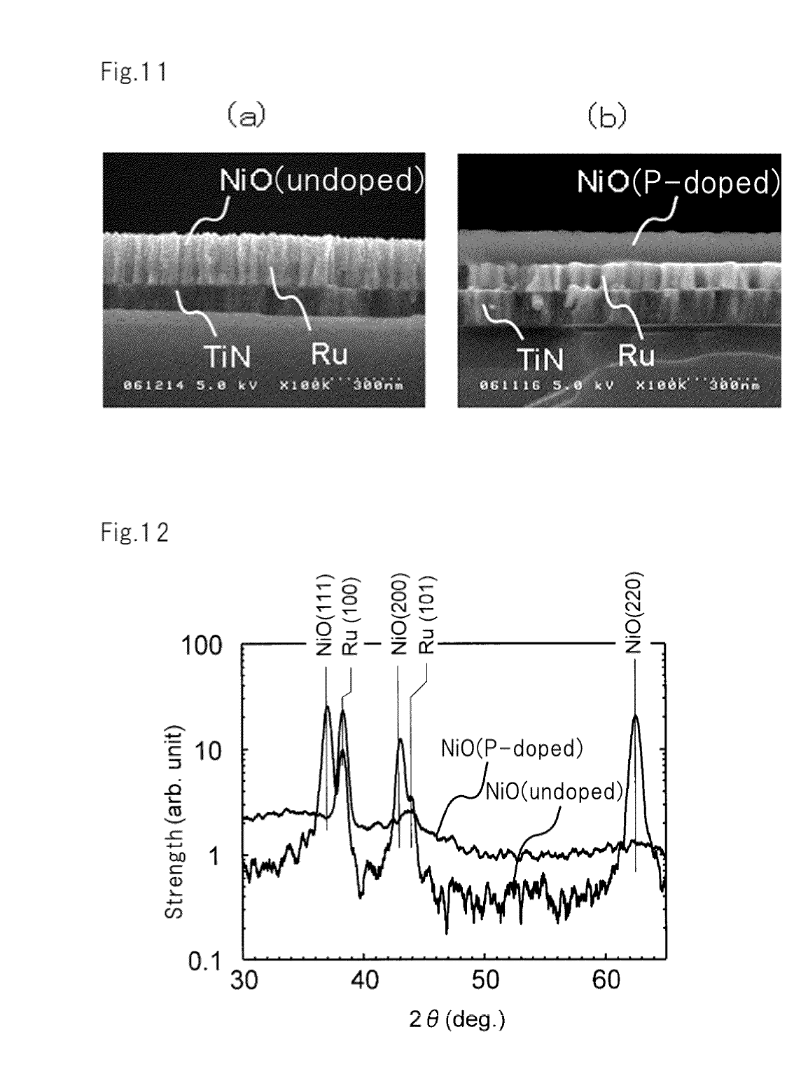

FIG. 11 is a drawing illustrating cross-sectional SEM images of a nickel oxide film formed on an Ru film. FIG. 11(a) illustrates an SEM image of a nickel oxide film not doped with P, whereas FIG. 11(b) illustrates an SEM image of a nickel oxide film doped with P. In the non-P-doped nickel oxide film of FIG. 11(a), crystal grains are clearly observed, whereas in the P-doped nickel oxide film of FIG. 11(b), the contrast of a cross section is uniform. Thus, FIG. 11(b) shows no contrast differences that reflect such a shape of crystal grains as observed in FIG. 11(a). In addition, by doping P, it is possible to form an NiO film having smaller surface roughness and a smaller film thickness distribution, compared with the non-P-doped nickel oxide film.

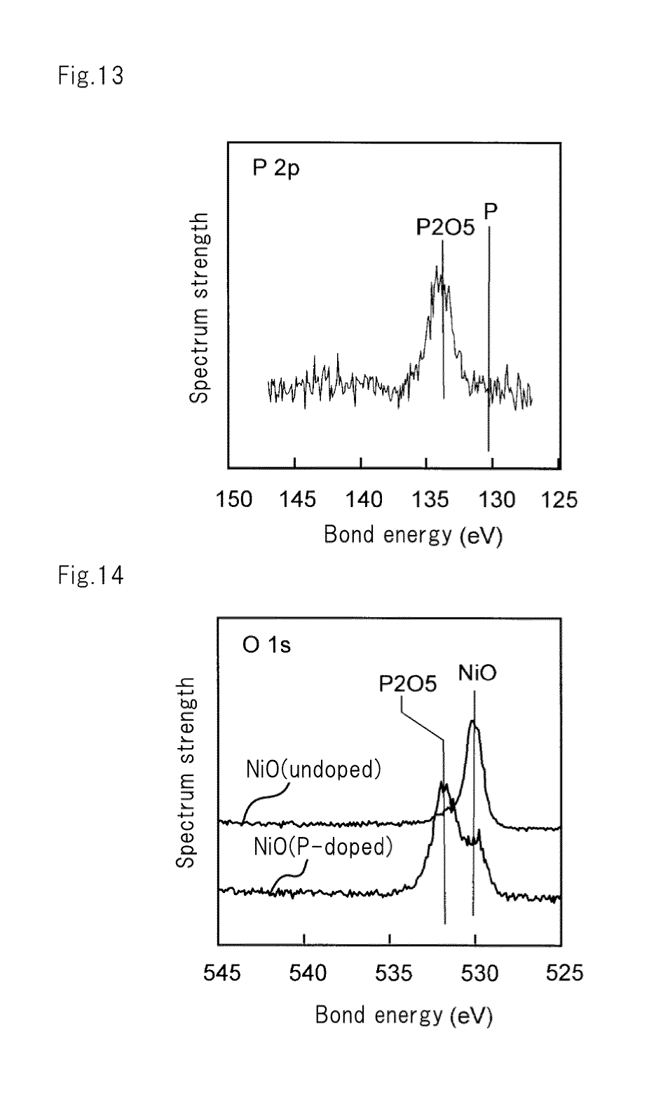

FIG. 12 is a drawing illustrating the results of the XRD measurement of a non-P-doped nickel oxide film and a P-doped nickel oxide film formed on an Ru film. In the non-P-doped nickel oxide film, distinct diffraction peaks attributable to Ni(111), Ni(200) and Ni(220) are detected. In the P-doped nickel oxide film, however, no diffraction peaks are detected. This means that a nickel oxide film, when doped with P, becomes uncrystallized. As shown by the P2p photoelectron spectrum of FIG. 13 and the O1s photoelectron spectrum of FIG. 14, P doped into the nickel oxide film oxidizes, forms a bonding state of P₂O₅, and is contained in the nickel oxide film. As described above, doping pentavalent P into divalent Ni causes the period of bonding of Ni with oxygen atoms to become irregular. Thus, it is possible to make the nickel oxide uncrystallized.

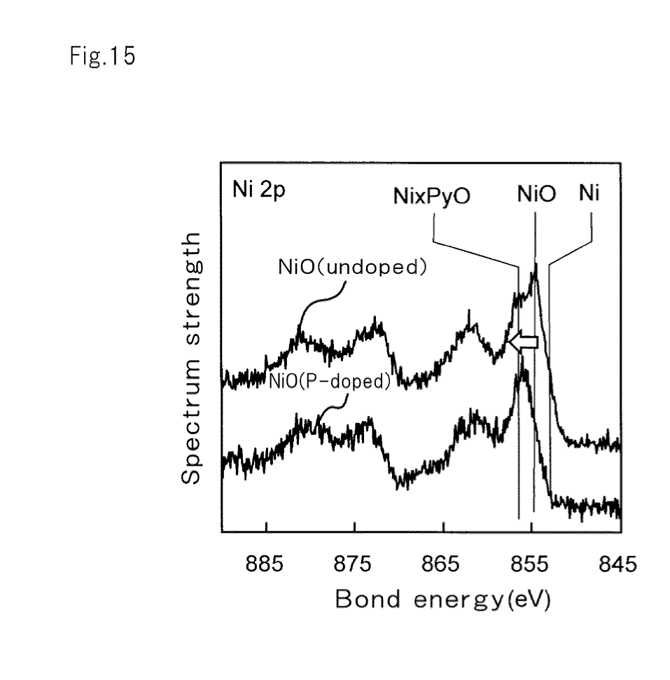

An oxide of divalent Ni forms NiO whose composition ratio of Ni to oxygen (O) is 1:1. On the other hand, an oxide of Ni doped with pentavalent P has a higher composition ratio of oxygen to Ni, compared with NiO. In addition, since P is higher in electronegativity than Ni, Ni combined with oxygen is affected by P serving as a second-neighbor atom. Consequently, the amount of charges transferred from Ni to oxygen becomes larger, compared with the amount in NiO, and the state of bonding between Ni and O becomes more stable. As illustrated in FIG. 15, the peak position of the Ni2p photoelectron spectrum of the P-doped nickel oxide film is located at a higher bond energy position, compared with that of the non-P-doped nickel oxide film. Thus, it is understood that the bonding state of Ni and O has become even more stable. As the result of Ni being in a more stable oxidized state, degradation in the film quality of the variable resistance material due to defect formation in the transition metal oxide is suppressed.

Next, as illustrated in FIG. 9(b), the upper Ru electrode layer 1, the variable resistance material layer (phosphorized nickel oxide layer) 11, and the lower Ru electrode layer 3 are processed into predetermined shapes using a lithography technique and a dry etching technique.

Next, as illustrated in FIG. 9(c), there is formed a sidewall protection film 17 for protecting the side surfaces of the MIM type variable resistance element. This sidewall protection film 17 also functions as an adhesion layer for preventing peel-off between the upper Ru electrode 1 and a later-formed interlayer insulating film 12. This sidewall protection film 17 is an insulating film, and a stable material superior in adhesiveness to the upper electrode, lower electrode, variable resistance material layer, and interlayer insulating film of the MIM type variable resistance element is used for the film. For example, a silicon nitride film (SiN) can be used.

Next, as illustrated in FIG. 9(d), an interlayer insulating film 12 is formed over the entire surface of the MIM type variable resistance element being fabricated.

Finally, as illustrated in FIG. 9(e), a via hole is formed in the upper electrode 1 and, using a CMP technique and a electrolytic plating technique, an upper via interconnect 18 is formed.

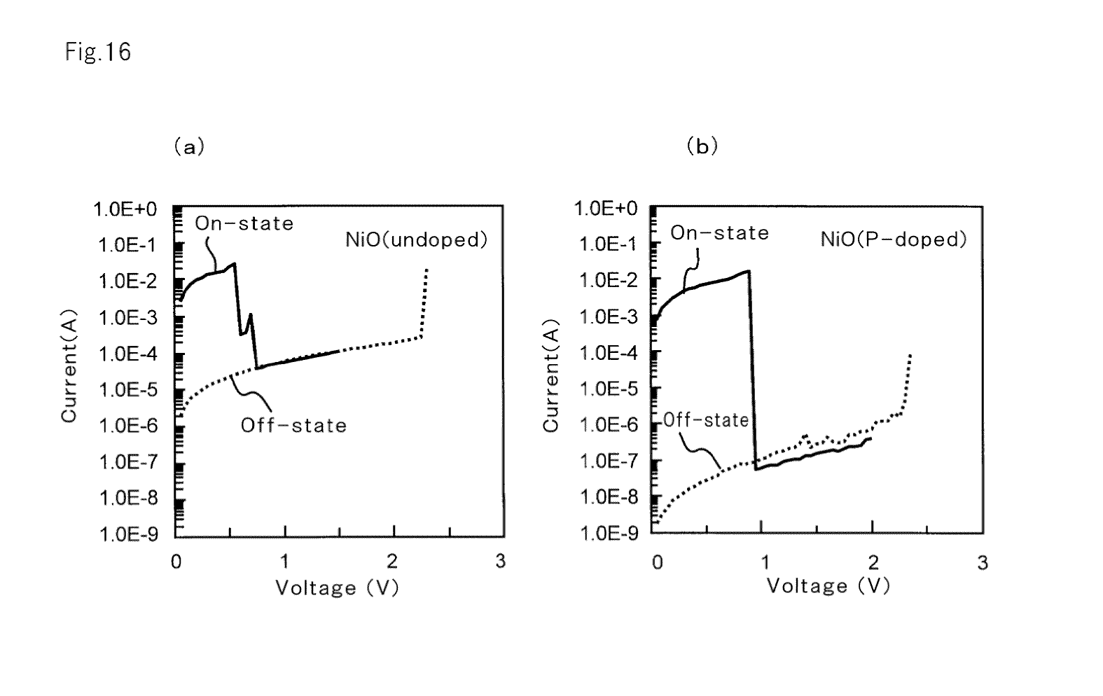

FIG. 16 illustrates the current-voltage characteristics (I-V characteristic) of the MIM type variable resistance element fabricated in this way. FIG. 16(a) illustrates the characteristics when a non-P-doped nickel oxide film is used, whereas FIG. 16(b) illustrates the characteristics when a P-doped nickel oxide film is used. It is understood that, as illustrated in FIG. 16, leakage currents and the variation of element characteristics attributable to a film thickness distribution and a crystal grain boundary can be suppressed by doping a suitable amount of P into the nickel oxide film and thereby making the nickel oxide film uncrystallized. In the MIM type variable resistance element which uses the non-P-doped nickel oxide film, a current ratio between the on- and off-states of switching operation is on the order of 2.5 digits. In contrast, in the MIM type variable resistance element which uses the P-doped nickel oxide film, it is understood that leakage currents in the off-state of switching operation are greatly reduced, a current ratio between the on- and off-states on the order of 5 digits or higher is obtained, and the switching operation characteristics of the MIM type variable resistance element are greatly improved.

### Exemplary Embodiment 2

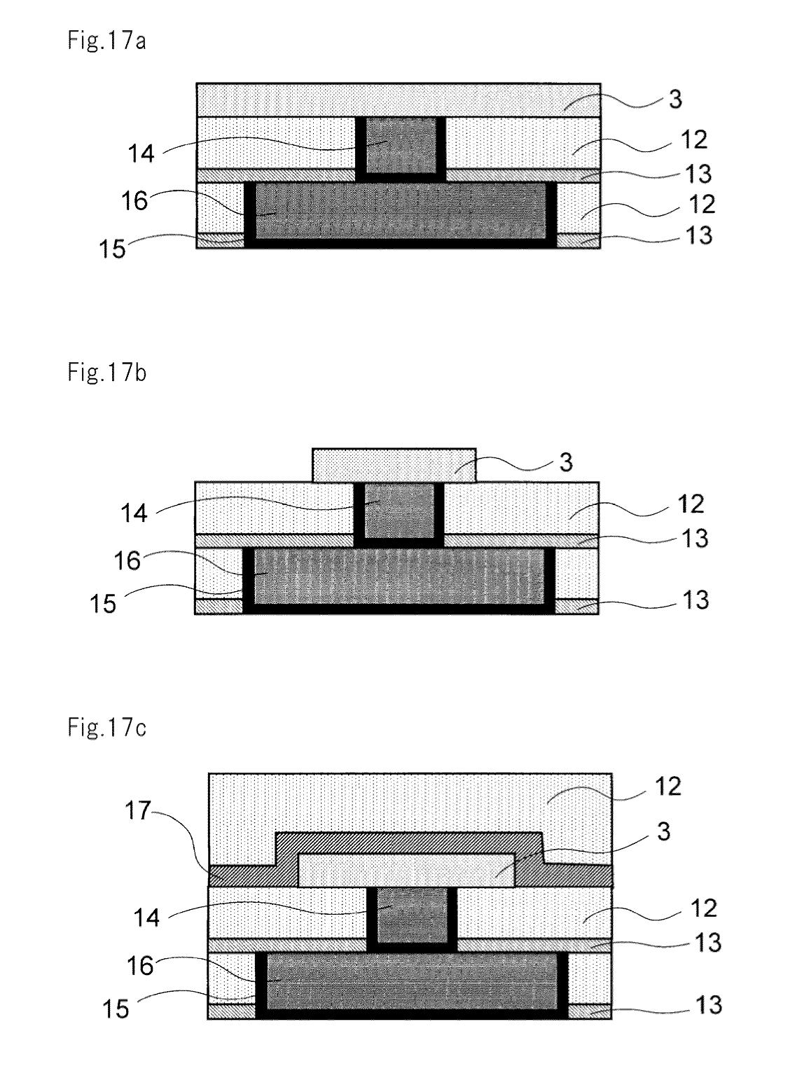

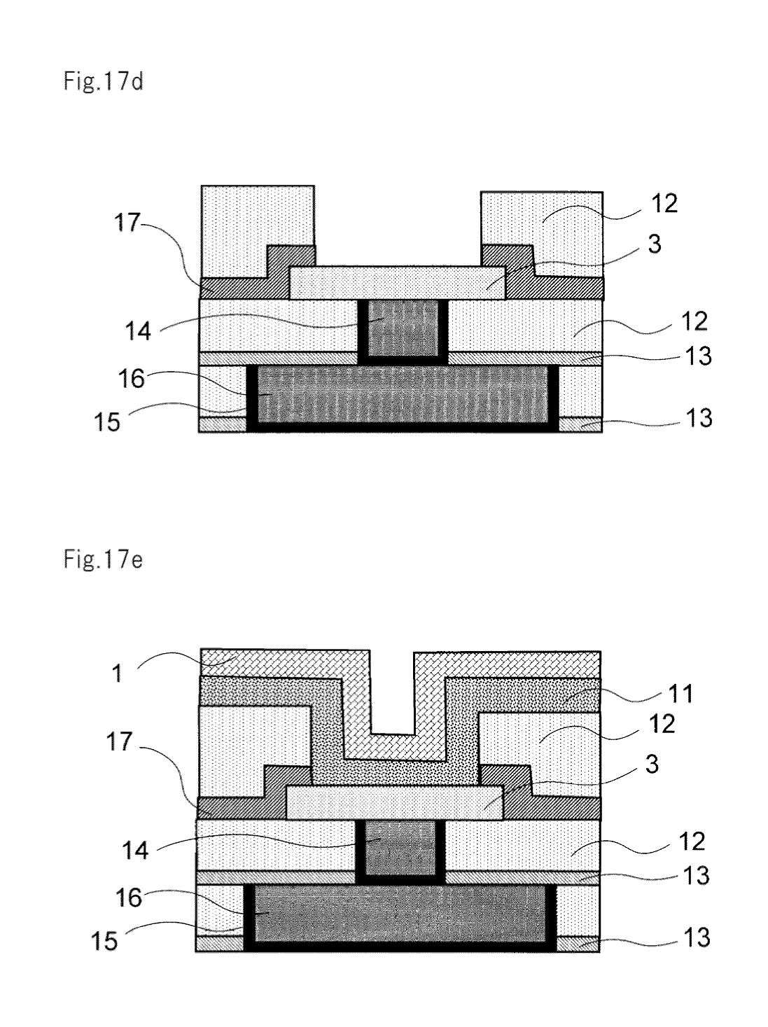

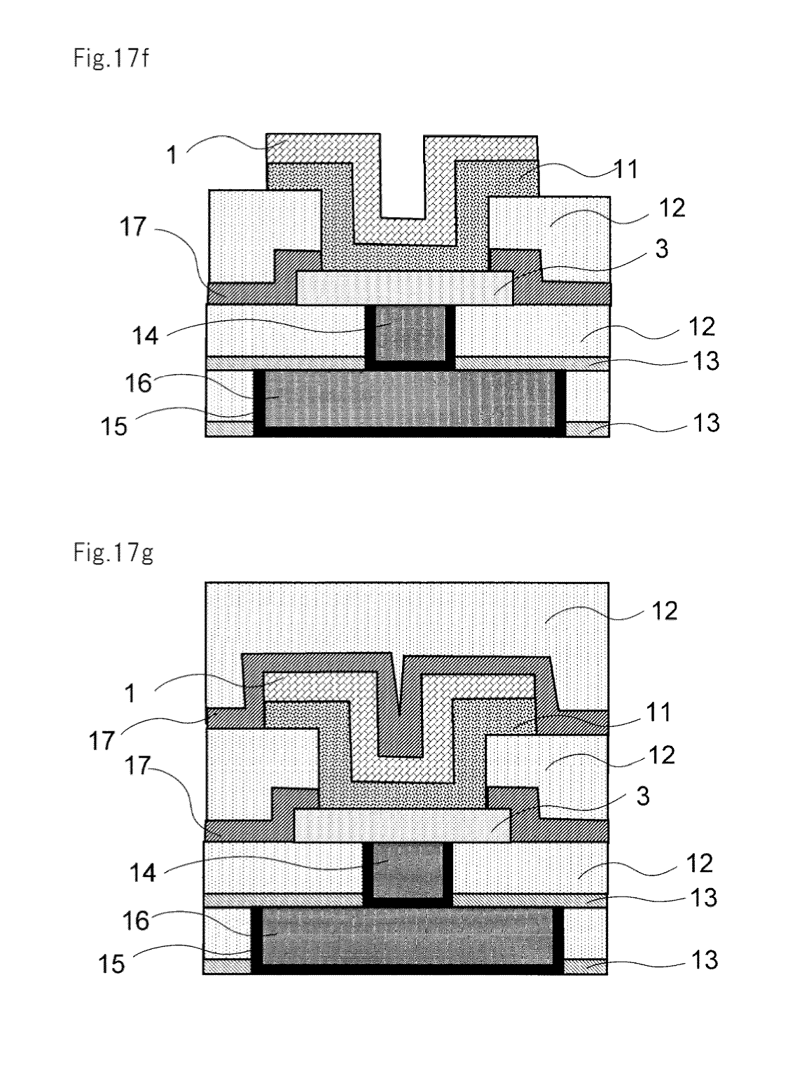

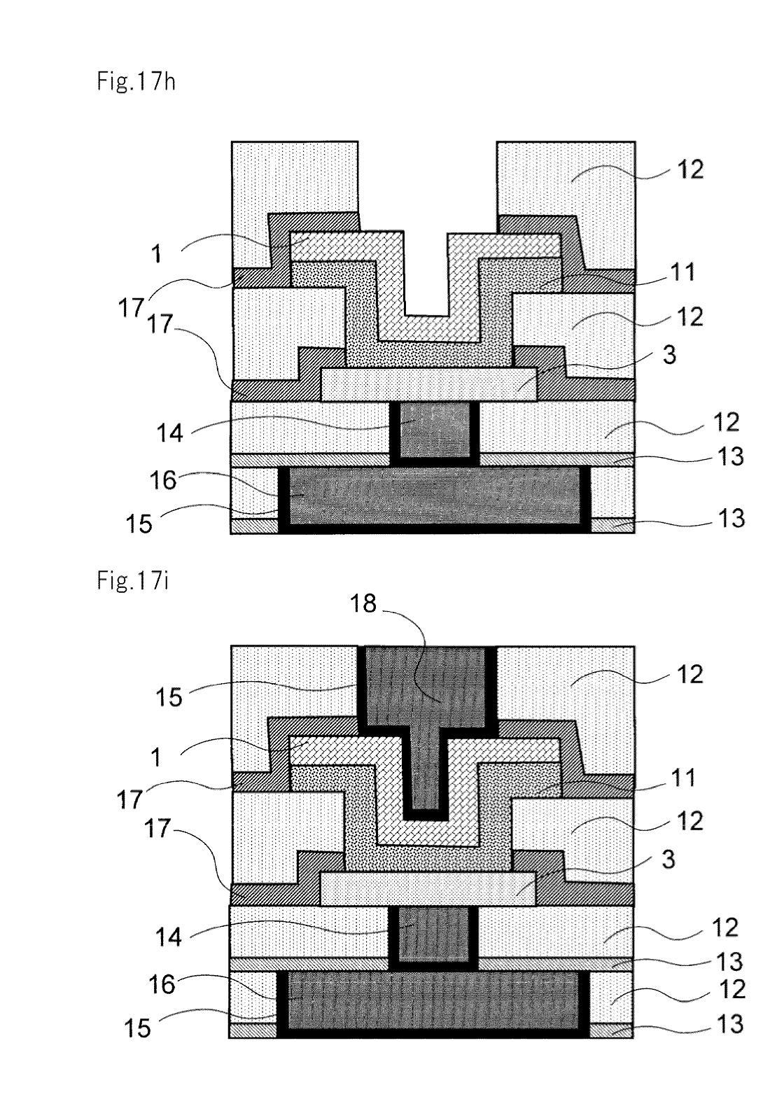

As a second exemplary embodiment of the present invention, FIG. 17(g) illustrates a structural example in which a hole is formed in an interlayer insulating film of LSI interconnects, and an MIM type variable resistance element is buried in the hole. Using FIGS. 17(a) to 17(g), a description will be made of the fabrication process of the MIM type variable resistance element of the present exemplary embodiment. This manufacturing process is an example of forming an MIM type variable resistance element to be connected to an interconnect layer of an LSI containing CMOS transistors.

First, as illustrated in FIG. 17(a), a lower interconnect 16 and a lower via interconnect 14 to be connected thereto are formed using a CMP technique and an electrolytic plating technique, and a lower electrode layer 3 of the MIM type variable resistance element is formed thereon. The manufacturing process up to this stage can be carried out in the same way as in Exemplary Embodiment 1.

Next, as illustrated in FIG. 17(b), the lower electrode layer 3 is processed into a predetermined shape using a lithography technique and a dry etching technique. In the present exemplary embodiment, both the lower electrode 3 and an upper electrode 1 to be formed in a subsequent step are made of Ru for ease of processing. Ru for the upper electrode 1 and the lower electrode 3 can be film-formed by means of sputtering.

Next, as illustrated in FIG. 17(c), there is formed a protection film 17 for protecting a surface of the lower electrode 3. After that, an interlayer insulating film 12 is formed. This protection film 17 also functions as an adhesion layer for preventing peel-off between the lower Ru electrode 3 and the interlayer insulating film 12. The protection film 17 is an insulating film, and a stable material superior in adhesiveness to the lower electrode 3 and a later-formed variable resistance material layer of the MIM type variable resistance element is used for the film. For example, a silicon nitride film (SiN) can be used.

Next, as illustrated in FIG. 17(d), the interlayer insulating film 12 and the protection film 17 in a predetermined region are removed using a lithography technique and a dry etching technique, thereby forming a hole on the lower electrode 3. This hole is formed so as to expose only a upper surface of the lower electrode 3 and not to expose any other portions thereof.

Next, as illustrated in FIG. 17(e), a variable resistance material layer (P-doped nickel oxide layer) 11 and an upper electrode layer 1 are formed. The P-doped nickel oxide film for constituting the variable resistance material layer 11 can be formed by means of sputtering. From the viewpoint of improving film denseness, however, the P-doped nickel oxide film is preferably formed using a CVD method. The manufacturing process of the P-doped nickel oxide film can be carried out in the same way as in Exemplary Embodiment 1.

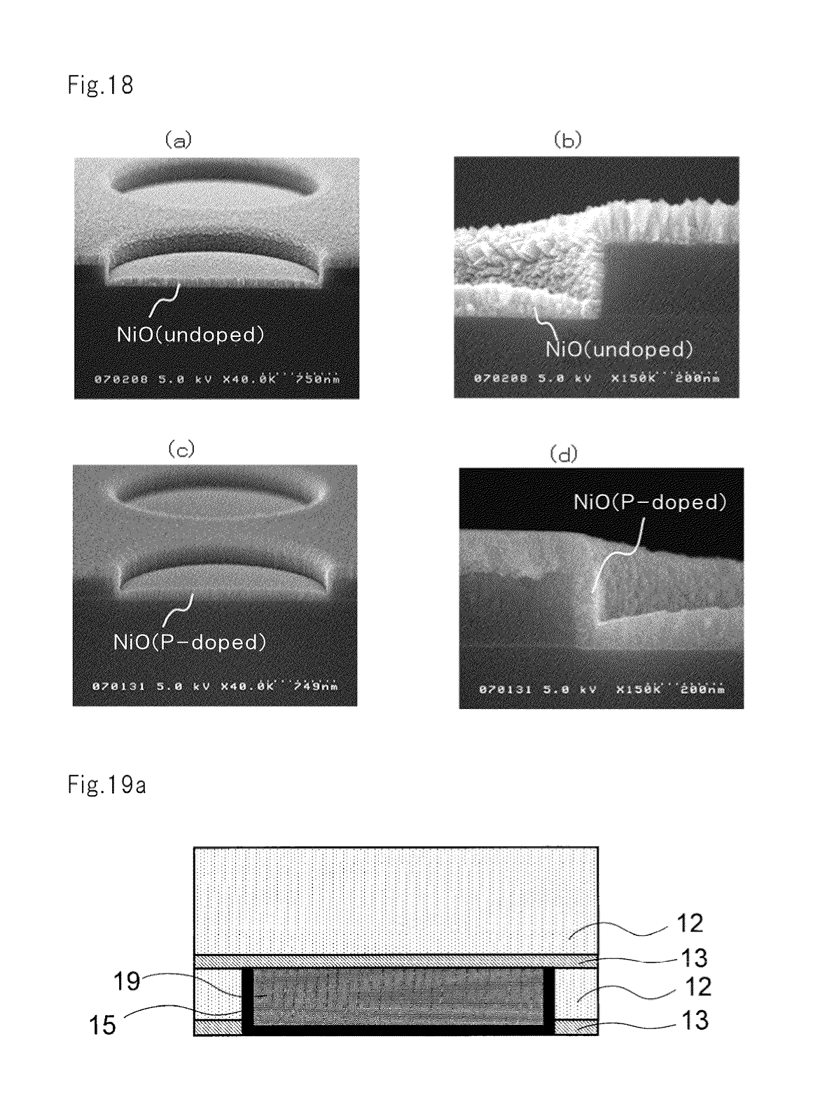

FIG. 18 illustrates cross-sectional SEM images of regions near the hole of the nickel oxide film. FIGS. 18(a) and 18(b) illustrate SEM images for a non-P-doped nickel oxide film, whereas FIGS. 18(c) and 18(d) illustrate SEM images for a P-doped nickel oxide film. As illustrated in FIGS. 18(a) and 18(b), crystal grains grow in the non-P-doped nickel oxide film, thus giving rise to large film thickness distributions in the sidewalls and the bottom edges of the hole. On the other hand, as illustrated in FIGS. 18(c) and 18(d), the contrast of a cross section is uniform in the P-doped nickel oxide film. Thus, FIGS. 18(c) and 18(d) show no contrast differences that reflect such a shape of crystal grains as illustrated in FIGS. 18(a) and 18(b). That is, doping P makes the nickel oxide film uncrystallized and suppresses surface roughness and film thickness distributions. Thus, it is possible to form a uniform nickel oxide film conforming to the shape of the hole.

Next, as illustrated in FIG. 17(f), the upper Ru electrode layer 1 and the variable resistance material layer 11 are processed into predetermined shapes using a lithography technique and a dry etching technique.

Next, as illustrated in FIG. 17(g), a protection film 17 for protecting the side surfaces of the MIM type variable resistance element is formed and an interlayer insulating film 12 is formed thereon. This protection film 17 also functions as an adhesion layer for preventing peel-off between the upper Ru electrode 1 and the interlayer insulating film 12. The protection film 17 is an insulating film, and a stable material superior in adhesiveness to the upper electrode, lower electrode and variable resistance material layer of the MIM type variable resistance element, and to interlayer insulating film is used for the film. For example, a silicon nitride film (SiN) can be used.

Next, as illustrated in FIG. 17(h), there is formed a hole in which the upper electrode 1 is exposed.

Finally, as illustrated in FIG. 17(i), an upper via interconnect 18 is formed in the hole with the intervention of a barrier film 15 using a CMP technique and an electrolytic plating technique.

By forming the MIM type variable resistance element into such a structure as described in the present exemplary embodiment, it is possible to prevent the variable resistance material layer from suffering damage in processing by dry etching. Accordingly, it is possible to improve the switching characteristics and the reliability of the MIM type variable resistance element.

### Exemplary Embodiment 3

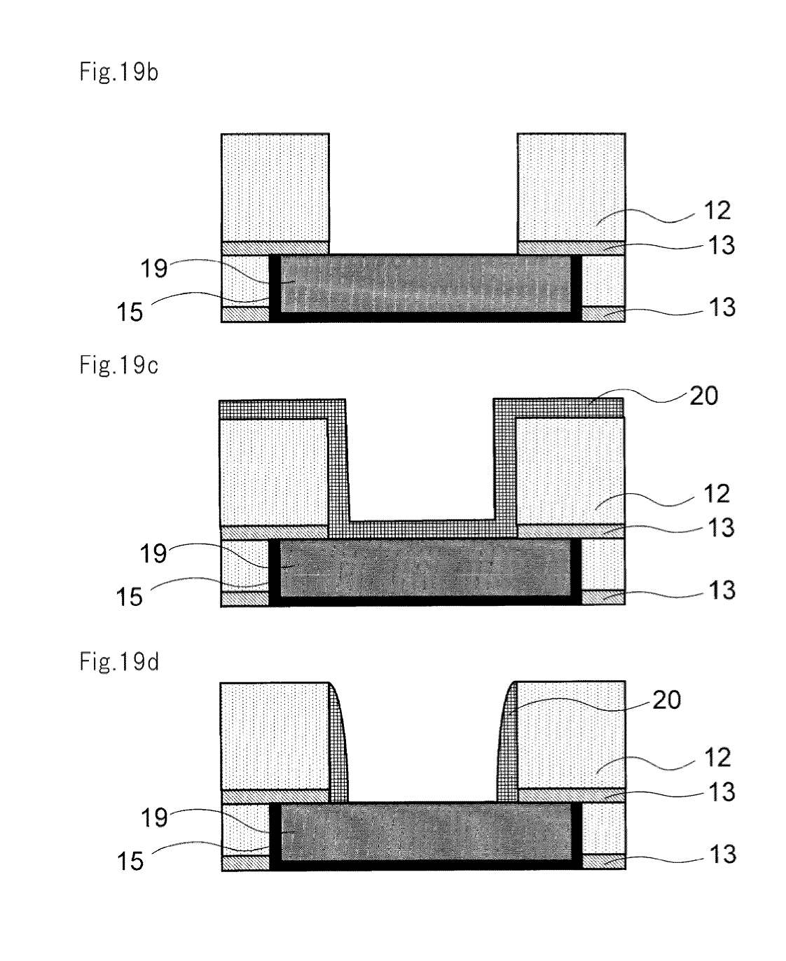

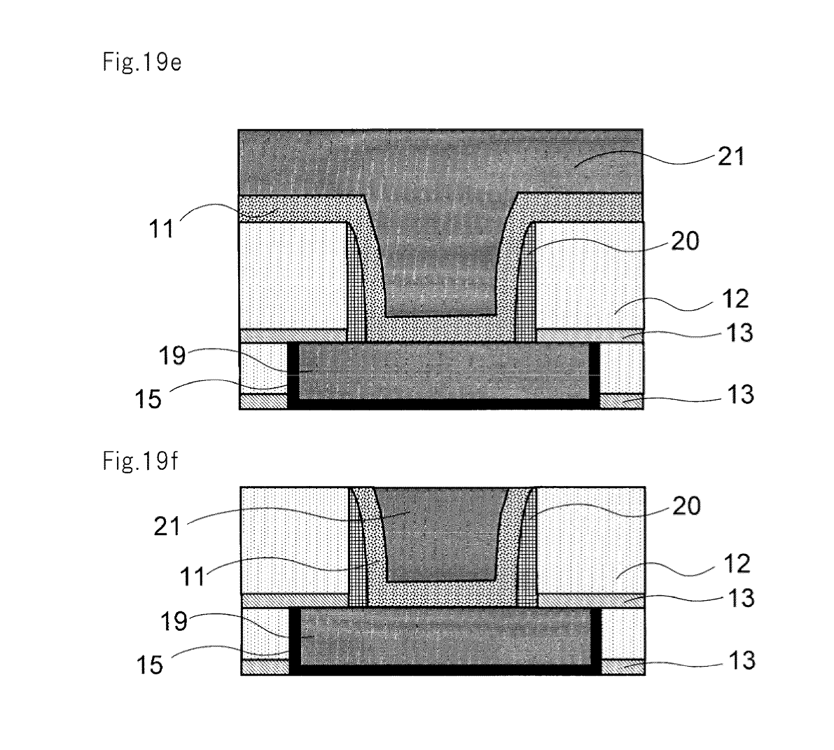

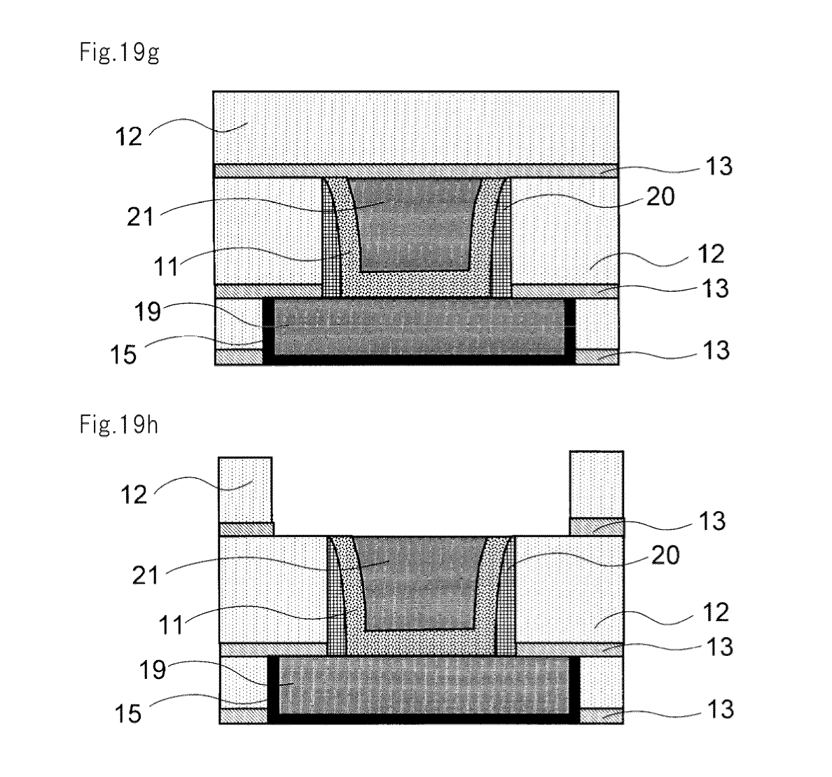

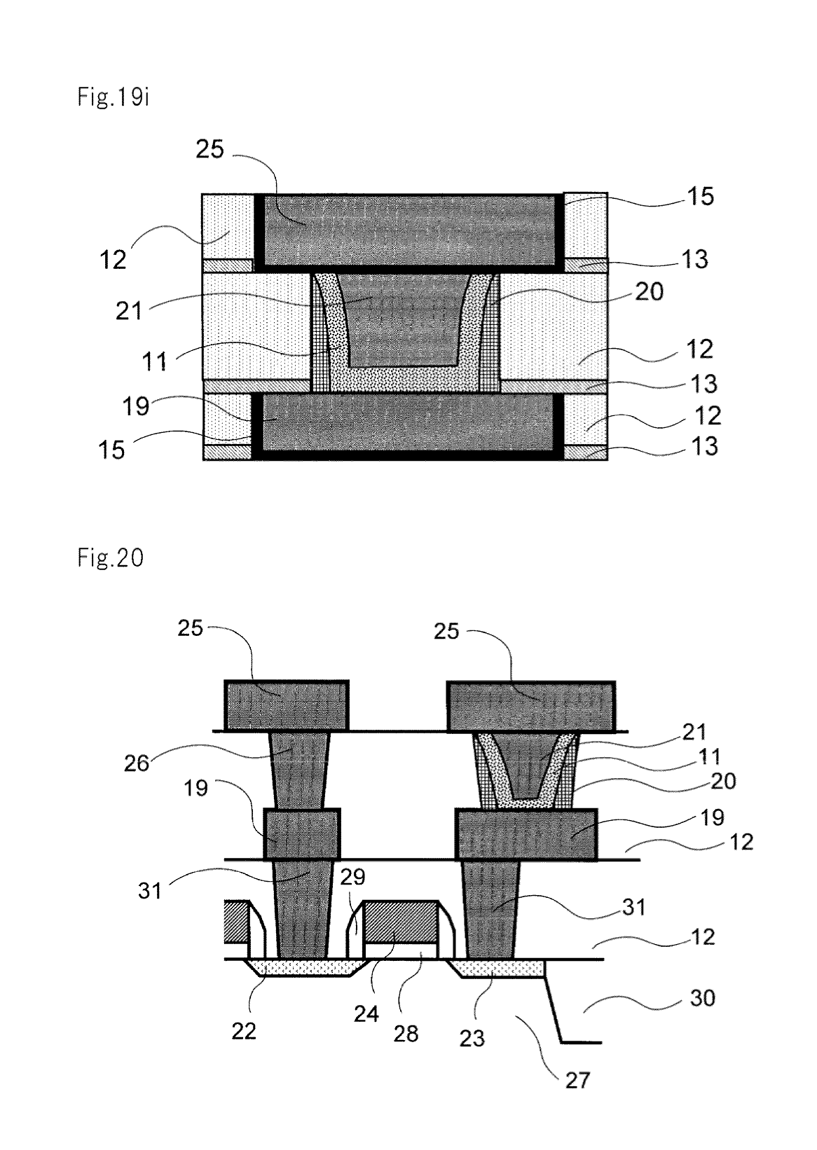

As a third exemplary embodiment of the present invention, FIG. 19(i) illustrates a structural example in which a hole is formed in an interlayer insulating film of LSI interconnects, an MIM type variable resistance element is buried in the hole, and the upper and lower electrodes of the MIM type variable resistance element and the LSI interconnects are used in common with each other. Using FIGS. 19(a) to 19(i), a description will be made of the fabrication process of the MIM type variable resistance element of the present exemplary embodiment. This manufacturing process is an example of forming an MIM type variable resistance element in which interconnect layers of an LSI containing CMOS transistors are used as electrodes.

First, as illustrated in FIG. 19(a), a lower interconnect 19 is formed using a CMP technique and an electrolytic plating technique. The manufacturing process up to this stage can be carried out in the same way as in Exemplary Embodiment 1. In the present exemplary embodiment, the lower interconnect 19 is utilized as the lower electrode of the MIM type variable resistance element. This lower electrode is made of Cu.

Next, as illustrated in FIG. 19(b), an interlayer insulating film 12 and a protection film 13 in a predetermined region are removed using a lithography technique and a dry etching technique, thereby forming a hole on the lower interconnect 19 constituting the lower electrode. This hole is formed so as to expose only an upper surface of the lower interconnect 19 and not to expose any other portions thereof.

Next, as illustrated in FIG. 19(c), a protective adhesion layer 20 is formed, in order to protect the interlayer insulating film 12 and enhance the adhesiveness thereof to a variable resistance material layer 11. The protective adhesion layer 20 is an insulating film, and a stable material superior in adhesiveness between the interlayer insulating film 12 and the variable resistance material layer 11 is used for the film. For example, a metal oxide film, a metal nitride, or a silicon nitride film (SiN) having no variable resistance characteristics can be used.

Next, as illustrated in FIG. 19(d), the protective adhesion layer 20 is left over only on the sidewall of the hole using a dry etching technique.

Next, as illustrated in FIG. 19(e), the variable resistance material layer (P-doped nickel oxide layer) 11 and an upper electrode layer 21 are formed. The P-doped nickel oxide film for constituting the variable resistance material layer 11 can be formed by means of sputtering. From the viewpoint of improving film denseness, however, the P-doped nickel oxide film is preferably formed using a CVD method. The manufacturing process of the P-doped nickel oxide film can be carried out in the same way as in Exemplary Embodiment 1. The upper electrode layer 21 is made of Cu and is formed using an electrolytic plating technique.

Next, as illustrated in FIG. 19(f), an excess variable resistance material layer 11 and upper electrode layer 21 are polished away by means of CMP to achieve planarization. Consequently, there is formed the upper electrode 21 of the variable resistance element. This upper electrode also functions as a via interconnect.

Next, as illustrated in FIG. 19(g), an interconnect protection film 13 and an interlayer insulating film 12 are formed on the upper electrode 21.

Next, as illustrated in FIG. 19(h), the interlayer insulating film 12 and the protection film 13 in a predetermined region are removed using a lithography technique and a dry etching technique, thereby forming a trench in which the upper electrode 21 is exposed, the trench being used for interconnect pattern formation.

Next, as illustrated in FIG. 19(i), an upper interconnect 25 is formed in the trench with the intervention of a barrier film 15 using a CMP technique and an electrolytic plating technique.

By applying such a process as described in the present exemplary embodiment, it is possible to build an MIM type variable resistance element into the via interconnect portion of an interconnect structure. By using the electrodes of the MIM type variable resistance element and interconnects in common with each other, it is possible to realize the improvement of switching characteristics due to the resistance reduction of an electrode material, the reduction of process costs, and the high integration of the MIM type variable resistance element.

FIG. 20 schematically illustrates a cross section of a structure in which the MIM type variable resistance element of the present exemplary embodiment is combined with a MOS type transistor. In the figure, reference numeral 12 denotes an interlayer insulating film, reference numeral 21 denotes a via interconnect constituting an upper electrode, reference numeral 22 denotes a source diffusion layer region, reference numeral 23 denotes a drain diffusion layer region, reference numeral 24 denotes a gate electrode, reference numeral 25 denotes an upper interconnect, reference numeral 26 denotes a via interconnect, reference numeral 27 denotes a silicon substrate, reference numeral 28 denotes a gate insulating film, reference numeral 29 denotes a gate sidewall, reference numeral 30 denotes an element-isolating region, and reference numeral 31 denotes a contact plug.

By connecting the lower interconnect 19 constituting the lower electrode of the MIM type variable resistance element in accordance with the present exemplary embodiment to the drain diffusion layer region 23 of the MOS type transistor through the contact plug 31, it is possible to realize a random access memory cell which is easy to highly integrate and has nonvolatility.

Having thus described the present invention with reference to the exemplary embodiments thereof, the present invention is not limited to the above-described exemplary embodiments. Alternatively, various modifications understandable to those skilled in the art may be made to the constitution and details of the present invention within the scope thereof.

This application claims the right of priority based on Japanese Patent Application No. 2007-147927, filed on Jun. 4, 2007, the entire content of which is incorporated herein by reference.

1. A variable resistance element comprising:
a first electrode;
a variable resistance material layer formed on the first electrode; and
a second electrode formed on the variable resistance material layer, wherein the variable resistance material layer is made of an uncrystallized material comprising a transition metal oxide, which is an oxide of a transition metal M1, the transition metal oxide containing an oxide of a nontransition metal element M2.

2. The variable resistance element according to claim 1, wherein the variable resistance material layer is made of an uncrystallized material comprising the transition metal oxide, which is an oxide of the transition metal M1, the transition metal oxide containing an oxide of the nontransition metal element M2 higher in valence than the transition metal M1.

3. The variable resistance element according to claim 1, wherein the variable resistance material layer is made of an uncrystallized material comprising the transition metal oxide, which is an oxide of the transition metal M1, the transition metal oxide containing an oxide of the nontransition metal element M2 higher in valence and electronegativity than the transition metal M1.

4. The variable resistance element according to claim 1, wherein the transition metal oxide is an oxide of at least one type of metal selected from the group consisting of Ni, Ti, Zr, Fe, V, Mn and Co.

5. The variable resistance element according to claim 1, wherein the transition metal oxide is an oxide of Ni.

6. The variable resistance element according to claim 1, wherein the oxide of the nontransition metal element M2 is an oxide of at least one type of element selected from the group consisting of P, As, Sb, Bi, Se, Te, Po, I, At, B, Al and Si.

7. The variable resistance element according to claim 1, wherein the oxide of the nontransition metal element M2 is an oxide of P.

8. A semiconductor device comprising:
a semiconductor substrate;
a transistor formed on the semiconductor substrate; and
a variable resistance element as recited in claim 1, the variable resistance element being electrically connected to the transistor.

9. A semiconductor device comprising:
a semiconductor substrate;
a transistor formed on the semiconductor substrate and provided with a source region and a drain region;
a variable resistance element as recited in claim 1,
wherein one of the electrodes of the variable resistance element is electrically connected to the source region or the drain region.

10. The semiconductor device according to claim 9, wherein one of the electrodes of the variable resistance element is electrically connected to the source region or the drain region through a barrier conductive layer.

11. The semiconductor device according to claim 9,
wherein the variable resistance element is located above the transistor with an intervention of an interlayer insulating film, and
one of the electrodes of the variable resistance element is connected to a conductive portion drawn from the source region or the drain region by penetrating through the interlayer insulating film.

12. A semiconductor device comprising:
a lower-layer interconnect;
an interlayer insulating film provided on the lower-layer interconnect; and
an upper-layer interconnect provided on the interlayer insulating film,
wherein the semiconductor device further comprises:
a variable resistance element as recited in claim 1;
a via hole provided in the interlayer insulating film such that the lower-layer interconnect is exposed;
a variable resistance material layer provided within the via hole; and
a conductive portion connecting to the upper-layer interconnect, the conductive portion being provided on the variable resistance material layer such that the via hole is filled with the conductive portion; and
wherein the variable resistance element comprises the lower-layer interconnect, the variable resistance material layer, and the conductive portion.

13. The variable resistance element according to claim 1,
wherein the transition metal oxide is an oxide of at least one type of metal selected from the group consisting of Ni, Ti, Zr, Fe, V, Mn and Co; and
the oxide of the nontransition metal element M2 is an oxide of at least one type of element selected from the group consisting of P, As, Sb, Bi, Se, Te, Po, I, At, B, Al and Si.

14. The variable resistance element according to claim 1,
wherein the transition metal oxide is an oxide of Ni; and
the oxide of the nontransition metal element M2 is an oxide of P.
